(19) United States
(12) Patent Application Publication
(10) Pub. No.: US 2025/0208638 A1
(43) Pub. Date: Jun. 26, 2025

(54) LEVEL SHIFT AND FUNCTIONAL CIRCUITS WITH EOS PROTECTION

(71) Applicant: Intel Corporation, Santa Clara, CA (US)

(72) Inventors: Andres GALAN, North Plains, OR (US); Praveen MOSALIKANTI, Portland, OR (US); Muquit SHAIKH, Portland, OR (US); Kuan-Yueh SHEN, Portland, OR (US); Qi WANG, Portland, OR (US); Syed Feruz SYED FAROOQ, Hillsboro, OR (US)

(21) Appl. No.: 18/392,148

(22) Filed: Dec. 21, 2023

(51) Int. Cl. G05F 1/56; H03K 17/08; H03K 19/0175

(52) U.S. Cl. CPC G05F 1/56; H03K 17/08; H03K 19/0175

(57) ABSTRACT

In some embodiments, bias circuits are provided that can generate resilient output supplies without consuming excessive power. In addition, other resilient and efficient bias circuits may be provided that can be used for biasing level shift and other high supply circuit blocks such as LDOs with thin gate transistors over a relatively wide high supply voltage operational range.

### TECHNICAL FIELD

Embodiments of the invention relate to the field of integrated circuits and more particularly, to circuits for implementing circuits in multi-supply domains with electrical overstress (EOS) protection.

### BRIEF DESCRIPTION OF THE DRAWINGS

The disclosure may best be understood by referring to the following description and accompanying drawings that are used to illustrate embodiments of the invention. In the drawings:

FIG. 1A is a block diagram generally showing a conventional scheme for controlling functional blocks in an integrated circuit (IC) when control circuitry and the functional blocks being controlled operate at different supplies.

FIG. 1B is a schematic showing a conventional level shift circuit with EOS protection circuits.

FIG. 1C shows a similar circuit as with FIG. 1B but with a more weakly driven VccH/2 circuit that makes the level shift circuit vulnerable to EOS.

FIG. 2 is a block diagram of a circuit having both low and high voltage circuitry implemented with thin gate transistors with EOS protection in accordance with some embodiments.

FIG. 3 is a schematic diagram showing a multi-voltage LDO in accordance with some embodiments.

FIGS. 4A and 4B are schematic diagrams illustrating mid level (Vb) bias generator circuits for generating a VccH/2 bias signal in accordance with some embodiments.

FIG. 5 is a schematic diagram showing a bias generator circuit for generating p and n bias signals in accordance with some embodiments.

FIG. 6 is a schematic diagram showing an exemplary circuit for biasing a multiplicity of mid-level (Vb) loads such as level shift circuits in accordance with some embodiments.

FIGS. 7A-7D are diagrams illustrating EOS Off-state issues for an LDO driver in accordance with some embodiments.

FIGS. 8A-8B are diagrams illustrating an EOS protection circuit for LDO reference circuitry in accordance with some embodiments.

FIG. 9 shows a full swing level shift circuit in accordance with some embodiments.

FIG. 10 shows another example of a full swing level shift circuit that may be used in accordance with some embodiments.

FIG. 11 illustrates an example computing system in accordance with some embodiments.

FIG. 12 illustrates a block diagram of an example processor and/or SoC 1200 that may have one or more cores and an integrated memory controller in accordance with some embodiments.

### DETAILED DESCRIPTION

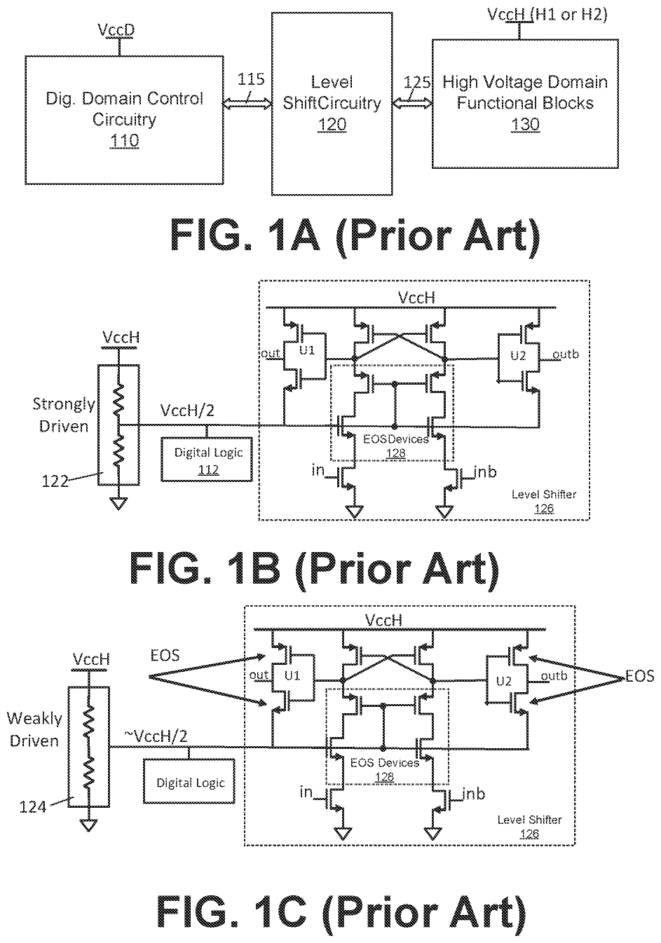

FIG. 1A is a block diagram generally showing a conventional scheme for controlling functional blocks in an integrated circuit (IC) when control circuitry and the functional blocks to be controlled operate at different supplies. Control circuitry 110 operating at a digital supply voltage (VccD) controls functional circuit blocks 130 operating at a higher supply voltage (VccH) through level shift circuitry 120. The digital control logic generates control signals 115, which may have high voltage levels in a range of between 0.5 and 1.0 or so V. On the other hand, control signals 125 coming from the level shift circuitry 120, in some embodiments, may have high voltage levels in a range from 1.1 to 1.9 V in order to adequately control the functional blocks operating at the higher supply voltage (VccH). Accordingly, the level shift circuitry 120 includes a plurality of level shift circuits with transistor configurations for transitioning control signals between these domains.

A low drop-out voltage regulator (LDO) is an example of a functional block within high supply domain 130. LDO regulators (LDOs) generally take in a higher voltage as input and provide a well regulated, lower output voltage. For some IC designs, with the progress of transistor technology nodes and upgrades of different specifications and standards, the high supply voltage may be at One of several different high level options, depending on a particular customer's implementation. That is, the functional block (e.g., LDO) cells must be capable of operating at a high supply (VccH) level that is at One of two (H1 or H2) different levels. For example, the H1 VccH voltage may be at a level in the range of between 1.05 and 1.4 V, while the higher H2 VccH voltage may be at a level in the range of between 1.56V and 1.9 V. With previous designs, separate functional circuits were employed, One for the H1 supply and the other for the H2 supply. The manufacturer or customer would then later select, e.g., through fuse selection or the like, the particular block to be activated. As can be readily appreciated, this approach is highly inefficient. Thus, it is desirable to have an LDO design that can operate seamlessly to support both high voltage (VccH) levels, e.g., H2 of 1.8V and H1 of 1.2V.

Ad added challenge is that in some designs, thin gate (oxide) technologies are used where the voltage drop across a transistor's gate oxide (gate-source or gate-drain) must be less than a maximum level, e.g., 1V or less, to avoid electrical overstress (EOS). This is true even for the level shift and functional block circuits that may be required to operate at the high supply (VccH) levels, which as mentioned above, can be as high as 1.9 or so V. Designing circuits with Only thin gate transistors that operate in this high voltage zone is complex since the design must guarantee transistor junction voltages below its EOS limits during any operating conditions, active and inactive supply sequences where EOS drops could occur. There have been many different approaches to achieve EOS robustness.

FIG. 1B is a schematic showing a conventional level shift circuit with EOS protection circuits. The circuit includes an always-On strongly driven divide-by-two bias (VccH/2) circuit 122 for driving EOS protection transistors (transistors) 128 within cross-coupled level shifter circuit 126. All of the depicted transistors are thin-gate transistors and thus, may not, for example, have their gates to source, or gates to drain, voltage drops exceed 1V.

Digital domain logic circuitry (e.g., from Dig. Logic 112) controls the level shifter at its inputs (in/inb) with digital domain voltage levels (e.g., 0V and 0.55V) for low and high logic signals, respectively. In turn, the level shifter outputs corresponding VccH level output values (VccH and VccH/2) at its complementary output nodes (out/outb) for controlling VccH functional control inputs within the VccH domain 130. For this to work, however, the always-On ½ voltage divider, which is essentially composed of stacked diode-connected transistors, must operate at a relatively high current level (e.g., hundreds if not thousands of uA), which is excessive, especially considering how many instantiations of these circuits are typically employed in many IC designs.

FIG. 1C shows a similar circuit but with a more weakly driven VccH/2 circuit 124. For example, the voltage divider branch may be driven at a relatively weak 10 or 20 uA to meet power limitations. Unfortunately, with this weaker bias implementation, VccH/2 voltage can decrease due to the non-trivial current load from the digital block 112. For example, with VccH equal to 1.8V, the bias output, instead of providing a consistent 0.9 V may droop as low as 0.6 V. As indicated in the figure, this can result in an over EOS voltage condition across One or more of the inverter (U1, U2) transistors as a result of the inverter's N-type transistor sources going down to the drooped VccH/2 level. Accordingly, new approaches for avoiding EOS violations and at the same time not consuming excessive power are desired.

In some embodiments, bias circuits are provided that can generate resilient output supplies without consuming excessive power. In addition, other resilient and efficient bias circuits may be provided that can be used for biasing level shift and other high supply circuit blocks such as LDOs with thin gate transistors over a relatively wide high supply voltage operational range.

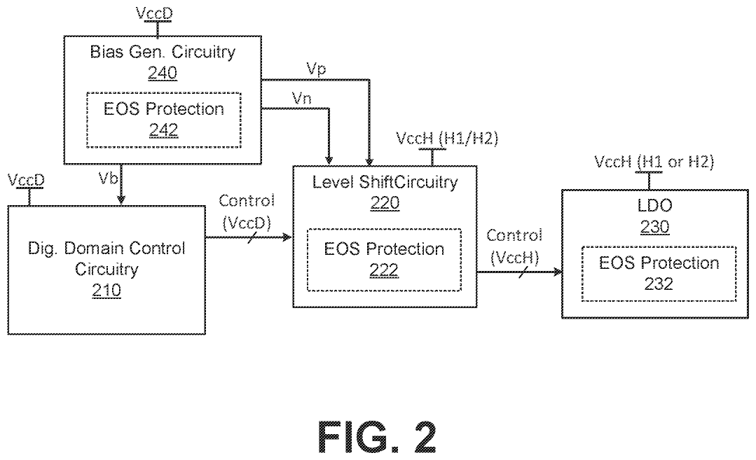

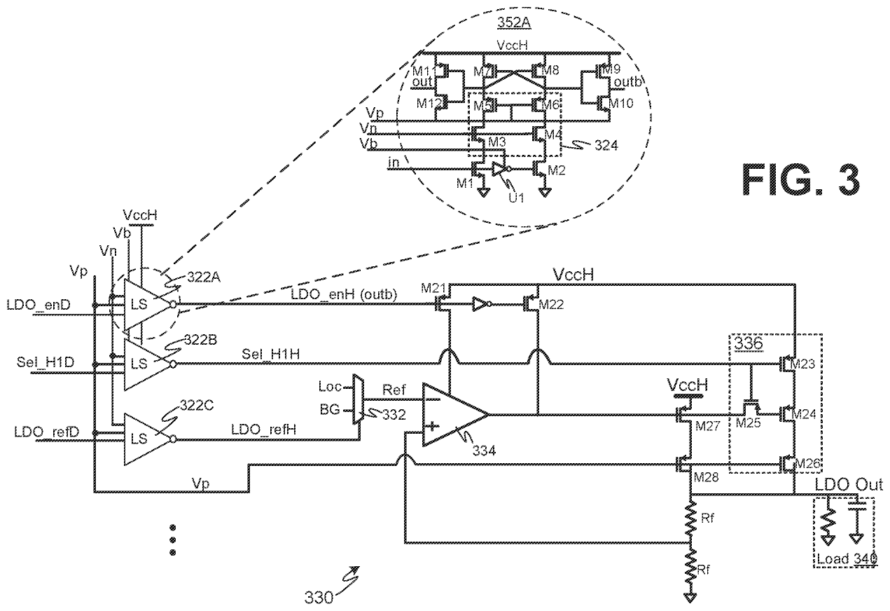

FIG. 2 is a block diagram of a circuit having both low and high voltage circuitry implemented with thin gate transistors with EOS protection in accordance with some embodiments. The circuit includes digital domain control circuitry 210 coupled through level shift circuitry 220 to a multiple high-voltage capable functional (e.g., LDO) circuit 230 for control thereof. The level shift, LDO and bias generator circuits each have EOS protection circuits 222, 232 and 242, respectively. The bias generator circuit 240 generates bias signals Vb, Vn, and Vp to operate the digital domain, level shift and LDO blocks in concert with their respective EOS protection circuits.

In the depicted embodiment, the high supply (VccH) is one of at least two high supply options H1 or H2. For example, H1 may be a value around 1.2 V while H2 is a larger value, e.g., around 1.8 V. The selected option, H1 or H2, may be fixed, e.g., from a factory setting, or in some embodiments, dynamically changeable, depending on design considerations. (For simplicity, and case of explanation, the remaining description will use 1.2 V and 1.8 V as exemplary H1 and H2 high supply (VccH) levels, but it should be appreciated that inventive embodiments should not be construed to be limited in this way.)

The digital domain control circuitry 210 operates Off of a digital supply (VccD) and a protection transistor bias (hereinafter referred to as Vb, e.g., VccH/2 or some other fraction of VccH), while the level shift and LDO circuits operate from the high supply (VccH) and the protection bias (Vb), p device bias (Vp), and n device bias (Vn) supplies as shown. Vb is used as an internal supply for the LDO enabling digital logic (including power level shifters and logic gates) coming from the digital domain 220. For example, VccD may be about 0.55 V. For the H2 (VccH=1.8 V) mode, the mid-level p and n bias voltages (Vp and Vn) are ½ VccH (0.9 V) for the thin gate protection transistors inside the LDO and level shift circuits. In H1 mode, the Vp bias voltage is ¼ VccH for the PMOS EOS protection transistors and Vn is ¾ VccH for the NMOS EOS protection transistors, resulting in their consuming little voltage headroom during LDO On states, regardless of whether the H1 or H2 high supply level is being used. In some embodiments, the protection bias Vb and p and n bias voltages (Vp, Vn) may be substituted for each other, depending on design considerations, for example, when Vb provides a VccH/2 bias level, it may be used for either the n or p bias voltages, e.g., when VccH is at H2.

In some embodiments, the depicted circuitry can facilitate LDO operation over a relatively wide supply voltage range, even with capacitive loads ranging from 65 to 250 pF. Moreover, in an Off state, very little leakage current (10 to 20 uA) may be achieved, even with the use of always-On bias generation circuits. Furthermore, the LDO design can generate an output voltage level with reduced noise, independent of the input supply while maintaining good stability, PSR (power supply rejection), and low settling time; thereby reducing a need for multiple LDO designs based on the utilized supply rail.

FIG. 3 is a schematic diagram showing a multi-voltage LDO in accordance with some embodiments. The LDO 330 is controlled by level shifted signals from level shift circuits 322, which convert digital domain control signals (LDO_enD, Sel_H1D, and LDO_refD into corresponding higher level (VccH) control signals LDO_cnH, Sel_H1H, and LDO_refH, as shown. Also shown is an exemplary level shift circuit 322A for implementing some or all of the level shift circuits 322.

The depicted level shift circuit is a cross-coupled level shift circuit with EOS protection circuitry 324, which includes N type transistors M3, M4 and P type transistors M5, M6. M3 and M4 are biased using Vn, while M5 and M6 are biased with Vp. The EOS protection transistors serve to prevent the output driver transistor (M9-M12) gate to source/drain drops from being subjected to EOS voltage levels, e.g., in excess of 1 V or so. The protection bias (Vb) supplies power to an inverter U1 used to generate a complementary input (inb) to facilitate a single-ended level shift input (in) to provide a differential drive input for the level shift circuit.

The LDO 330 has enable/disable switches M21, M22 that power on LDO amplifier 334 when LDO_enH is asserted (Low), which turns On M21 an turns Off M22. LDO Amplifier 334 receives a reference input (Ref) from multiplexer 332, either a locally generated reference or a bandgap reference, at in inverting input and a feedback signal from the LDO output (LDO-Out) by way of resistor divider feedback resistors (Rf) at a non-inverting input to provide a well regulated output voltage (LDO_Out) to load 340. The LDO also has a first driver, formed from one or more P-type transistors M27, to modulate power provided at the output based On the output of the amplifier 334, and it has an EOS protection transistor M28, biased from Vp, to protect the driver transistor(s) M27 from electrical over stress voltages. (Note that with some designs, the EOS protection transistors may be biased with the protection bias, Vb, which is typically VccH/2 or it may be biased with Vp, which is VccH/2 when the supply is at its higher level but may be smaller, VccH/4 when the supply is at the lower level.)

In some embodiments, the LDO may also include a supplemental (second) power driver, formed from One or more transistors M24, in parallel with the primary (first) driver transistor(s) M27 to supplement power to the load when the LDO is in the lower H1 supply mode. In some embodiments, the supplemental driver M24 may be twice as strong as the primary driver M27. Included with the supplemental driver transistor(s) M24 are enable/disable supply switch transistors M23, M25, controlled by the Sel_H1 signal, and an EOS protection transistor M26 to prevent the supplemental power regulation transistor M24 from being exposed to EOS voltages across its gate dielectric. The supplemental driver(s) M27 operates to balance the drive strength loss when the lower input supply is used. Additional switches (not shown) within the amplifier to couple VccH to the output may also be activated to increase the drive strength of the P-type drivers and increase the tail current, thereby maintaining a high enough loop gain for regulation.

The depicted thin-gate LDO can generate an EOS Protection bias based on the input supply to maintain a high enough loop gain during normal operation. For instance, in H2 (1.8V) mode, the EOS protection bias is ½ VccH for the NMOS and PMOS EOS protection transistors, and in H1 (1.2 V) mode, the EOS protection bias is ¼ VccH (0.3 V) for the PMOS transistors and ¾ VccH (0.9 V) for the NMOS transistors.

(It is pointed out that transistor reference labels, Mi, are used independently for each figure so as to avoid overly large and incumbering labels. M1 in one figure may correspond to a completely different M1 transistor in another figure. the descriptions and transistor labels for each figure stand on their own, again, for case of presentation, although in some cases, they correspond to the same functional device.)

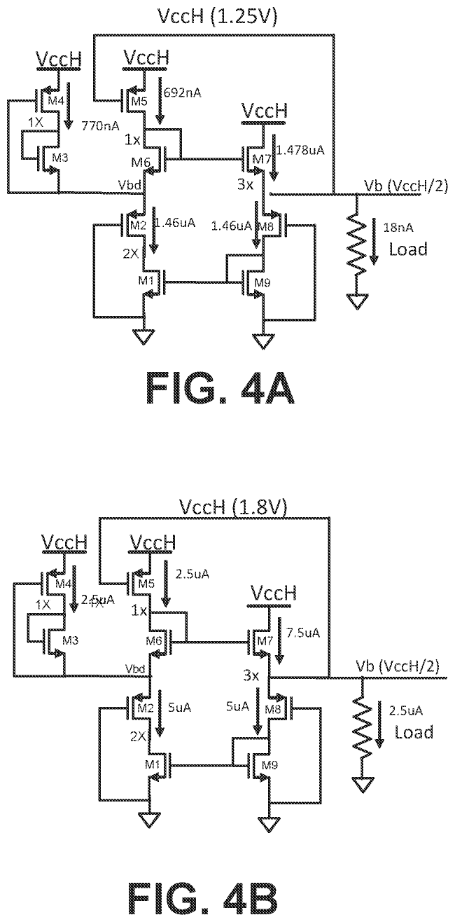

FIGS. 4A and 4B are schematic diagrams illustrating protection bias (Vb) generator circuits for generating a protection bias signal (Vb) that is sufficiently stable to maintain a consistent bias voltage over a relatively wide output load range (e.g., up to tens of mA) while consuming relatively very little current (e.g., 10 to 20 uA). FIG. 4A shows the circuit with a high VccH supply of 1.8 V, while FIG. 4B shows the circuit with a high supply of 1.25 V. With these examples, the circuits are configured to generate a VccH/2 protection bias (Vb) level.

The protection bias generator circuit includes transistors M1-M9 coupled as shown. M3/M4 and M5/M6 form equally sized parallel branches that feed into a lower branch formed from M1 and M2, which are twice as large as each of the above branches, thereby making the lower branch equivalent with the overall upper branches. The upper branches and lower branch effectively form a voltage divider (divide-by-two in this case) circuit, providing a VccH/2 voltage at the bias divide (Vbd) node. The upper half is split into two legs so as to reduce the current through transistor M6.

Transistors M7-M9 form an output section to provide the generated output bias voltage (Vb). With M6 and M7 coupled, as shown, M6 and M7 will have very close to the same gate-to-source voltage (Vgs). In this example, the bias current and the width of transistor M7 is 3× larger compared to M6 so that M7 can drive higher current loads. However, because the output current load varies across PVT (process, voltage, and temperature), the output voltage may not stay fix, thereby causing potential EOS problems downstream. Therefore, negative feedback is incorporated as shown. In this embodiment, two negative feedback loops are implemented. One is from the output to the gate of transistor M5, and the other through transistor M9 as its current is mirrored to transistor M1. The M5 voltage feedback loop increases the voltage overdrive (Vgs) of transistor M5 and the gate of the source follower driver M7 if the output voltage decreases thereby increasing the source of M7 and correcting the output voltage from sagging. Similarly, if the output voltage decreases, the current source M1, M9 will try to keep the current through M1 and M9 the same by decreasing the VGS of transistors M1 and M9, thereby increasing the source voltage of M6 and M7. Thus, as can be seen, the depicted bias generator can provide a consistent bias voltage (e.g., VccH/2) with different high supply levels, over a wide output load range and at the same time, consume relatively low amounts of always On current.

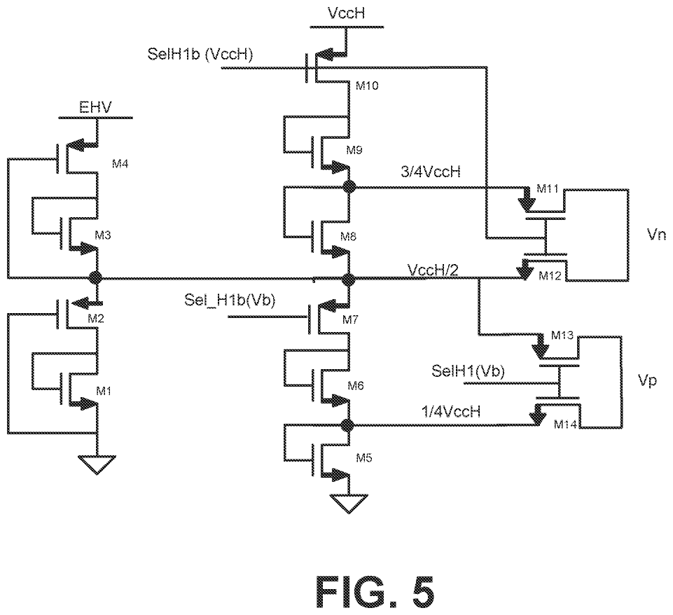

FIG. 5 is a schematic diagram showing a bias generator circuit for generating p and n bias signals in accordance with some embodiments. The circuit includes transistors M1-M14 coupled together as shown. Transistors M1-M4 are equivalently sized and are each diode connected and coupled together in series, functioning together as a first voltage divider circuit with VccH/2 provided at a midpoint node, as indicated at VccH/2. Similarly, transistors M6-M9 are also equivalently sized and each diode connected and in series with One another, forming a second voltage divider circuit that is enabled or disabled by switches M5 and M10. Transistors M11-M14 also function as switches. They control the tapped values to be provided Onto the Vp and Vn nodes, depending on whether the circuit is in VccH1 or VccH2 mode. When in VccH1 mode, transistors M5, M10, M11, and M14 turn On, resulting in Vp equal to ¼ VccH and Vn equal to ¾ VccH. The always On M1-M4 branch functions to serve as an anchor for the M6-M9 branch. When the circuit is in the VccH2 mode, transistors M5 and M10 turn Off, disabling the M6-M9 branch, and switches M12 and M13 turn On, providing both the Vp and Vn nodes with a bias level of VccH/2.

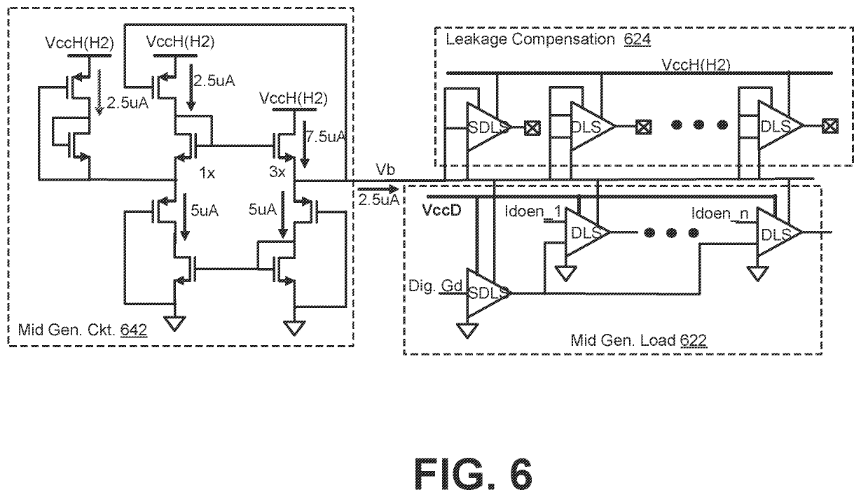

FIG. 6 is a schematic diagram showing an exemplary circuit for biasing a multiplicity of protection bias (Vb) loads such as level shift circuits in accordance with some embodiments. It includes a bias generation circuit 642, such as a circuit in accordance with FIG. 4A or 4B, coupled to a plurality of loads 622, level shifters in the depicted example, and leakage compensation loads 624 as shown. The loads 622 may include any suitable circuit such as self-deterministic level shift (SDLS) and deterministic level shift (DLS) circuits as indicated for enabling a plurality of LDOs Off of a master enable (Dig. Gd) control. The leakage reduction circuitry 624 includes replicas of the standard cell level shifters from the circuits of load 622 instantiated between the VccH and Vb rails to cancel the leakage of active level shifters between Vb and ground, thereby allowing additional digital logic to be driven by the Vb bias generator source follower branch with very little always-On current. For example, in some embodiments, this design can support a load of 20 or more level shifters consuming ˜2.5 uA when inactive in a 1.8 V VccH supply mode.

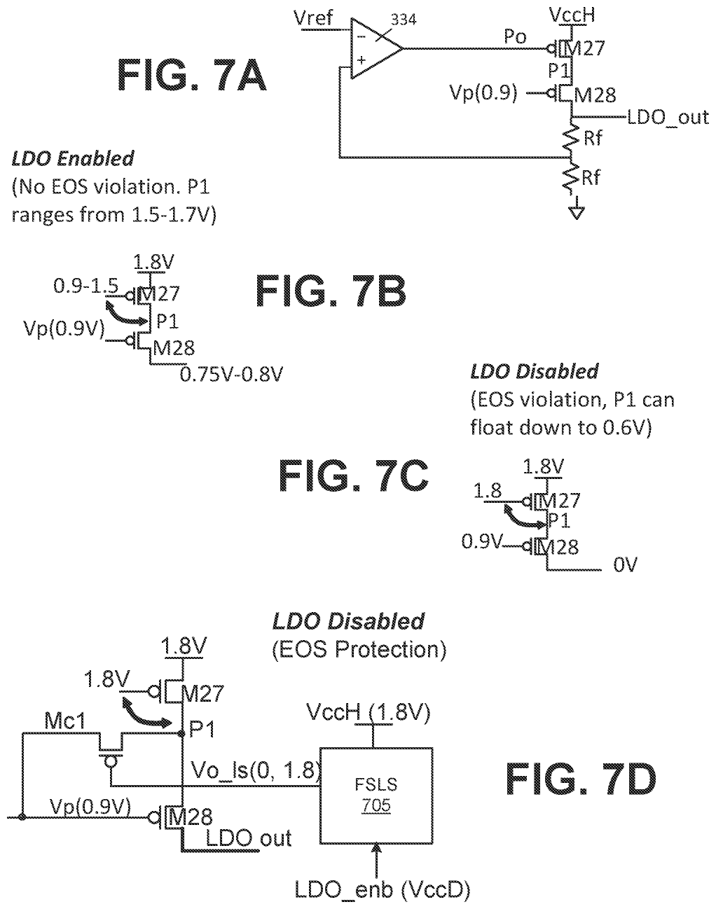

FIGS. 7A-7D are diagrams illustrating EOS Off-state issues for an LDO driver in accordance with some embodiments. FIG. 7A shows a portion of an LDO amplifier 324 having output node Po coupled to thin gate driver transistor M27, which is coupled to thin gate EOS protection transistor M28, as shown at node P1. When such circuits utilize high voltage supplies (e.g., in excess of 1.1 V, careful design is required to avoid EOS when the circuits are in their Off, as well as their On, states.

FIG. 7B shows the driver transistor M27 and protection transistor M28 in an On state with a VccH supply of 1.8 V. The EOS protection transistor M28, with a bias of 0.9 V (Vp), protects the driver transistor M27 as indicated with Vgs and Vgd drops for M27 not exceeding 1 V. However, when the LDO is turned Off, EOS violations may occur as described with reference to FIG. 7C.

FIG. 7C shows the driver circuit portion in an Off state. When in the Off state, there can be floating nodes that violate EOS limits. With the depicted embodiment, the amplifier output (Po) is pulled up to VccH (1.8V) when the LDO is turned Off. Since this turns Off the driver (M27), the P1 node floats, as low as 0.6 V, which imposes a 1.2 V EOS violation across the gate/drain of M27. An approach for addressing this problem is illustrated in FIG. 7D.

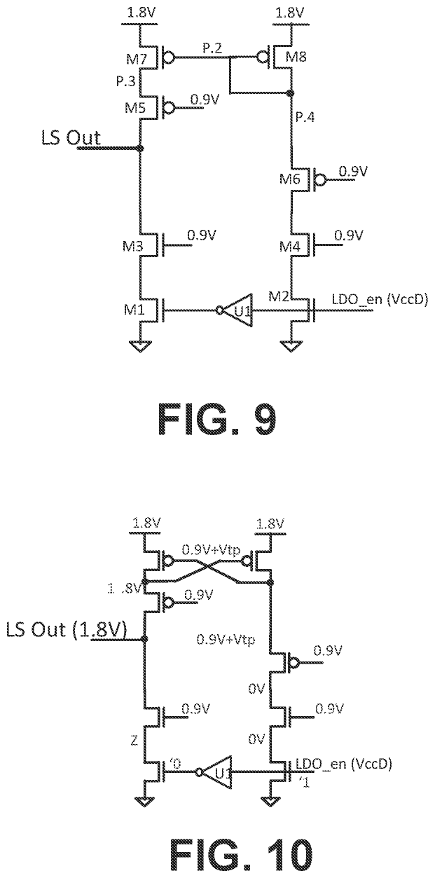

FIG. 7D shows the LDO driver circuit portion with circuitry to redress the Off-state EOS violation. The circuit includes an OFF-state protection (or clamping) transistor Mc1 to clamp the P1 node to the EOS protection transistor bias level (Vp), which is 0.9 V in this embodiment. It also includes a VccH tolerant full-swing level shifter (FSLS) 705 that is capable of providing a full-swing control (e.g., 0 V to 1.8 V), Off of a digital level control signal (e.g., 0 V to 0.55 V), to the clamp transistor Mc1. As will be discussed further below, FIGS. 9 and 10 show exemplary FSLS circuits that may be used for level shift circuit 705.

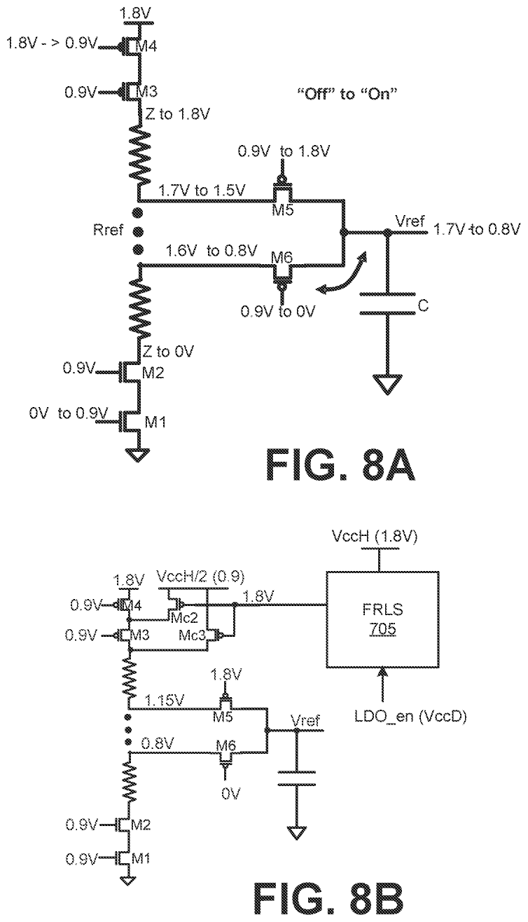

FIGS. 8A-8B are diagrams illustrating an EOS protection circuit for LDO reference circuitry in accordance with some embodiments. FIG. 8A illustrates EOS vulnerabilities that occur when the reference circuit transitions from an Off to an On state. The reference circuit includes a resistor reference ladder (Rref), e.g., from a programmable digital to analog converter (DAC), coupled between EOS protection transistors M2, M3 and supply switch transistors M1, M4 as shown. The circuit also includes Vref selection switches M5, M6, coupled as shown, to provide a voltage reference (Vref) at a reference input of an LDO. Also shown is a capacitor C, which is also part of the LDO reference input for filtering reference level noise. Also shown in the figure are exemplary voltage levels at various nodes from Off-state values to On-state values. As can be seen, in the Off state, M5 is On and M6 is Off, which places a value of 1.7 V at the Vref node. When the circuit is activated and M6 turns On with M5 turning Off, the M6 gate immediately goes to 0 V, but the 1.7 V level at Vref lingers due to the capacitor C, which induces a large EOS voltage (˜1.7 V) across the gate/source junction of M26 until the Vref level can settle to its On-state level of 0.8 V. An approach for addressing this problem is illustrated in FIG. 8B.

FIG. 8B is a schematic showing the reference circuitry of FIG. 8A with additional EOS protection circuitry for protecting transistors when the reference circuit transitions from Off to On. The circuit includes EOS clamp transistors Mc2 and Mc3, coupled as shown, with their sources coupled to a VccH/2 bias supply (e.g., Vp for VccH at 1.8 V and their gates coupled to an output of a level shift circuit such as full swing level shift circuit 705 for controlling the clamp transistors to be on during an Off state and Off during a reference circuit On state. The depicted figure shows voltage levels when the reference circuit is On with 0.8 V at its Vref output. When it is in an Off state, the clamp transistors ensure that the Vref level is not above 0.9 V, preventing EOS level drops across the gate junctions when the reference circuit transitions to the On state.

FIG. 9 shows a full swing level shift circuit in accordance with some embodiments. This circuit is suitable for use as a level shift circuit 705 in either of the circuits of FIG. 7B or 8B. Since traditional level shifters may be unavailable for use in an Off state, the level shift circuit of FIG. 9 uses a current mirror based level converter configuration, mirroring High and Low side transistor stacks to each other o provide high level binary swings (e.g., 0 V for Low and 1.8 V for High) from smaller, digital domain input control levels (e.g., 0V, 0.55 V). The circuit includes input driver transistors M1, M2, coupled through inverter U1, EOS protection transistors M3-M6, and mirrored cross-over transistors M7, M8, all coupled together as shown. The input, LDO_en (VccD), ranges from 0 to 0.55 V, while the output, LS Out, ranges from 0 to 1.8 V. When the input is Low (0 V), the left side transistor stack driver and protection transistor (M1, M3) turn On fairly strongly while the right side stack counterparts (M2, M4) are turned Off or at least On fairly weakly. This results in very little current flow in M8, and thus in M7, which is mirrored to M8, and M5, which is in series with M7. With M1 and M3 being On, the output (LS Out) will be at, or very near, 0 V. On the other hand, when the input, LDO_en (VccD) is at a High (0.55 V), M2 and M4 turn On with M1 and M3 turning Off. This allows M6 and M8 to turn on fairly strongly, which causes M7, and in turn, M5, to also turn on strongly, providing 1.8 V an the output (LS Out). In essence, the 0/0.55 V levels are up-shifted through the transistor stacks on either side of the circuit, resulting in a full swing level shift circuit that not only protects against thin gate EOS, but also, consumes relatively little current.

FIG. 10 shows another example of a full swing level shift circuit that may be used in accordance with some embodiments. The circuit replaces the current mirror level converter with a cross-coupled level converter structure. This circuit operates similarly with the circuit of FIG. 9 except that it uses cross-coupled cross-over (pull-up) transistors instead of mirrored transistors for controlling a pull-up transistor off of its counterpart stack without consuming excessive current.

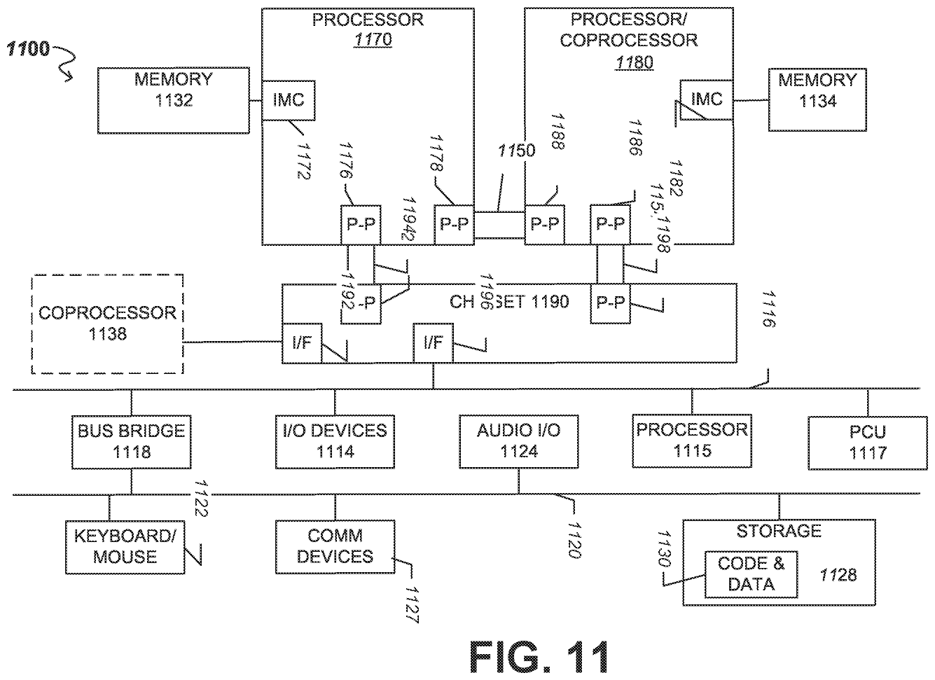

FIG. 11 illustrates an example computing system in accordance with some embodiments. Multiprocessor system 1100 is an interfaced system and includes a plurality of processors including a first processor 1170 and a second processor 1180 coupled via an interface 1150 such as a point-to-point (P-P) interconnect, a fabric, and/or bus. In some examples, the first processor 1170 and the second processor 1180 are homogeneous. In some examples, first processor 1170 and the second processor 1180 are heterogenous. Though the example system 1100 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 1170 and 1180 are shown including integrated memory controller (IMC) circuitry 1172 and 1182, respectively. Processor 1170 also includes interface circuits 1176 and 1178, along with core sets. Similarly, second processor 1180 includes interface circuits 1186 and 1188, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 1170, 1180 may exchange information via the interface 1150 using interface circuits 1178, 1188. IMCs 1172 and 1182 couple the processors 1170, 1180 to respective memories, namely a memory 1132 and a memory 1134, which may be portions of main memory locally attached to the respective processors.

Processors 1170, 1180 may each exchange information with a network interface (NW I/F) 1190 via individual interfaces 1152, 1154 using interface circuits 1176, 1194, 1186, 1198. The network interface 1190 (e.g., one or more of an interconnect, bus, and/or fabric, and in some examples is a chipset) may optionally exchange information with a coprocessor 1138 via an interface circuit 1192. In some examples, the coprocessor 1138 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 1170, 1180 or outside of both processors, yet connected with the processors via an interface such as P-P interconnect, such that either or both processors' local cache information may be stored in the shared cache if a processor is placed into a low power mode.

Network interface 1190 may be coupled to a first interface 1116 via interface circuit 1196. In some examples, first interface 1116 may be an interface such as a Peripheral Component Interconnect (PCI) interconnect, a PCI Express interconnect, or another I/O interconnect. In some examples, first interface 1116 is coupled to a power control unit (PCU) 1117, which may include circuitry, software, and/or firmware to perform power management operations with regard to the processors 1170, 1180 and/or co-processor 1138. PCU 1117 provides control information to one or more voltage regulators (not shown) to cause the voltage regulator(s) to generate the appropriate regulated voltage(s). PCU 1117 also provides control information to control the operating voltage generated. In various examples, PCU 1117 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

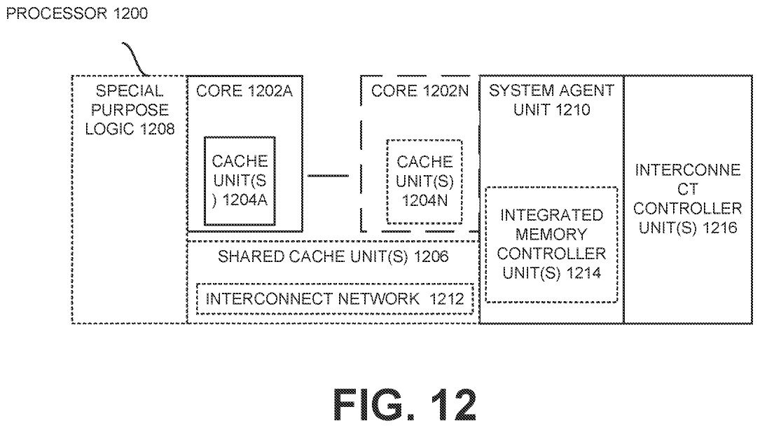

In some embodiments, either or both processors or co-processors may include LDOs for providing power to different power domains. Some or all of these LDOs may be configured in accordance with any of the embodiments disclosed herein and may be controlled via level shift circuitry in accordance with any of the embodiments disclosed herein to allow for lower voltage supply level control logic to control higher supply level LDOs, or other functional circuits, using thin gate transistors and having EOS protection. Along these lines, the LDOs and/or level sift circuits disclosed herein may be used to provide robust thin-gate circuitry for any of the IC blocks of FIG. 11 or FIG. 12 described below.

PCU 1117 is illustrated as being present as logic separate from the processor 1170 and/or processor 1180. In other cases, PCU 1117 may execute on a given one or more of cores (not shown) of processor 1170 or 1180. In some cases, PCU 1117 may be implemented as a microcontroller (dedicated or general-purpose) or other control logic configured to execute its own dedicated power management code, sometimes referred to as P-code. In yet other examples, power management operations to be performed by PCU 1117 may be implemented externally to a processor, such as by way of a separate power management integrated circuit (PMIC) or another component external to the processor. In yet other examples, power management operations to be performed by PCU 1117 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 1114 may be coupled to first interface 1116, along with a bus bridge 1118 which couples first interface 1116 to a second interface 1120. In some examples, one or more additional processor(s) 1115, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 1116. In some examples, second interface 1120 may be a low pin count (LPC) interface. Various devices may be coupled to second interface 1120 including, for example, a keyboard and/or mouse 1122, communication devices 1127 and storage circuitry 1128. Storage circuitry 1128 may be one or more non-transitory machine-readable storage media as described below, such as a disk drive or other mass storage device which may include instructions/code and data 1130 and may implement the storage in some examples. Further, an audio I/O 1124 may be coupled to second interface 1120. Note that other architectures than the point-to-point architecture described above are possible. For example, instead of the point-to-point architecture, a system such as multiprocessor system 1100 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

FIG. 12 illustrates a block diagram of an example processor and/or SoC 1200 that may have one or more cores and an integrated memory controller. The solid lined boxes illustrate a processor 1200 with a single core 1202(A), system agent unit circuitry 1210, and a set of one or more interface controller unit(s) circuitry 1216, while the optional addition of the dashed lined boxes illustrates an alternative processor 1200 with multiple cores 1202(A)-(N), a set of one or more integrated memory controller unit(s) circuitry 1214 in the system agent unit circuitry 1210, and special purpose logic 1208, as well as a set of one or more interface controller units circuitry 1216. Note that the processor 1200 may be one of the processors 1170 or 1180, or co-processor 1138 or 1115 of FIG. 11.

Thus, different implementations of the processor 1200 may include: 1) a CPU with the special purpose logic 1208 being integrated graphics and/or scientific (throughput) logic (which may include one or more cores, not shown), and the cores 1202(A)-(N) being one or more general purpose cores (e.g., general purpose in-order cores, general purpose out-of-order cores, or a combination of the two); 2) a coprocessor with the cores 1202(A)-(N) being a large number of special purpose cores intended primarily for graphics and/or scientific (throughput); and 3) a coprocessor with the cores 1202(A)-(N) being a large number of general purpose in-order cores. Thus, the processor 1200 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 1200 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 1204(A)-(N) within the cores 1202(A)-(N), a set of one or more shared cache unit(s) circuitry 1206, and external memory (not shown) coupled to the set of integrated memory controller unit(s) circuitry 1214. The set of one or more shared cache unit(s) circuitry 1206 may include one or more mid-level caches, such as level 2 (L2), level 3 (L3), level 4 (L4), or other levels of cache, such as a last level cache (LLC), and/or combinations thereof. While in some examples interface network circuitry 1212 (e.g., a ring interconnect) interfaces the special purpose logic 1208 (e.g., integrated graphics logic), the set of shared cache unit(s) circuitry 1206, and the system agent unit circuitry 1210, alternative examples use any number of well-known techniques for interfacing such units. In some examples, coherency is maintained between one or more of the shared cache unit(s) circuitry 1206 and cores 1202(A)-(N). In some examples, interface controller units circuitry 1216 couple the cores 1202 to one or more other devices 1218 such as one or more I/O devices, storage, one or more communication devices (e.g., wireless networking, wired networking, etc.), etc.

In some examples, one or more of the cores 1202(A)-(N) are capable of multi-threading. The system agent unit circuitry 1210 includes those components coordinating and operating cores 1202(A)-(N). The system agent unit circuitry 1210 may include, for example, power control unit (PCU) circuitry and/or display unit circuitry (not shown). The PCU may be or may include logic and components needed for regulating the power state of the cores 1202(A)-(N) and/or the special purpose logic 1208 (e.g., integrated graphics logic). The display unit circuitry is for driving one or more externally connected displays.

The cores 1202(A)-(N) may be homogenous in terms of instruction set architecture (ISA). Alternatively, the cores 1202(A)-(N) may be heterogeneous in terms of ISA; that is, a subset of the cores 1202(A)-(N) may be capable of executing an ISA, while other cores may be capable of executing only a subset of that ISA or another ISA.

Illustrative examples of the technologies disclosed herein are provided below. An embodiment of the technologies may include any one or more, and any compatible combination of, the examples described below.

Example 1 is an apparatus that includes a functional circuit, a level shift circuit, and a bias generation circuit. The functional circuit has a control input node. The level shift circuit has an output node coupled to the control input node to provide a shifted control voltage signal. The level shift circuit also has an electrical overstress (EOS) protection transistor with a protection bias gate input node. The bias generation circuit includes: (i) a voltage divider circuit formed from a first plurality of transistors to establish a divider voltage, and (ii) an output section including a second plurality of transistors with a bias output node coupled to the protection bias gate input node to provide a bias output voltage corresponding to the divider voltage. The output section is coupled to the voltage divider circuit to facilitate negative feedback control of the voltage divider circuit based on the bias output voltage.

Example 2 includes the subject matter of example 1, and wherein the functional circuit is a low drop-out (LDO) circuit.

Example 3 includes the subject matter of any of examples 1-2, and wherein the control node is coupled to gates of one or more supply transistors to enable or disable the LDO.

Example 4 includes the subject matter of any of examples 1-3, and wherein the LDO includes a supply node to receive a supply voltage that is one of at least first and second supply voltage levels, the second level being larger than the first level, wherein the LDO includes a driver transistor coupled to an LDO output node to provide a regulated LDO output voltage, and a second driver transistor controllably coupled to the LDO output node to supplement power to the LDO output node when the supply is at the first supply voltage level.

Example 5 includes the subject matter of any of examples 1-4, and wherein the LDO comprises an EOS protection transistor coupled between the first driver transistor and the LDO output node.

Example 6 includes the subject matter of any of examples 1-5, and wherein the EOS protection transistor has a gate coupled to an LDO bias voltage that is one-half the LDO supply level voltage.

Example 7 includes the subject matter of any of examples 1-6, and wherein the functional circuit, level shift circuit, first plurality of transistors, and second plurality of transistors are thin-gate transistors.

Example 8 includes the subject matter of any of examples 1-7, and wherein the voltage divider circuit is coupled between a supply node with a supply voltage that is higher than an EOS level for the first and second plurality of transistors and a ground reference node, the divider voltage to be one-half the supply voltage level.

Example 9 includes the subject matter of any of examples 1-8, and wherein the output section is coupled to the voltage divider circuit at a gate of a control transistor from the first plurality of transistors to facilitate a first negative feedback lop.

Example 10 includes the subject matter of any of examples 1-9, and wherein at least one of the output section second plurality transistors is coupled to at least one of the first plurality of transistors in a current mirror configuration to provide a second negative feedback loop.

Example 11 is an integrated circuit having one or more functional circuits, level shift circuits, and bias generation circuits as defined in the subject matter of any of examples 1-10.

Example 12 is a multi-chip package comprising at least one of the integrated circuits of example 11.

Example 13 is a circuit that includes a supply node and first and second driver transistors. The supply node is to receive a supply voltage that is one of at least first and second supply voltages. The second supply voltage is larger than the first supply voltage. The first driver transistor is coupled between the supply node and a regulator output node to provide a regulated voltage at the regulator output node. The second driver transistor is controllably coupled between the supply node and the regulator output node to be active and supplement power to the regulator output node when the supply is at the first supply voltage and is to be inactive when the supply node is at the second supply voltage.

Example 14 includes the subject mater of example 13, and further comprises one or more EOS protection transistors coupled between the supply node and the regulator output node, the one or more EOS protection transistors each having a gate coupled to an input bias node to receive a first bias voltage if the supply node is at the first supply voltage and to receive a second bias voltage if the supply node is at the second supply voltage.

Example 15 includes the subject matter of any of examples 13-14, and wherein a first of the one or more EOS protection transistors is coupled between the first driver transistor and the supply node.

Example 16 includes the subject matter of any of examples 13-15, and wherein a second of the one or more EOS protection transistors is coupled between the second driver transistor and the supply node.

Example 17 includes the subject matter of any of examples 13-16, and wherein a first of the one or more EOS protection transistors is coupled between the first driver transistor and the regulator output node.

Example 18 includes the subject matter of any of examples 13-17, and wherein a second of the one or more EOS protection transistors is coupled between the second driver transistor and the regulator output node.

Example 19 includes the subject matter of any of examples 13-18, and comprising a bias generator circuit having a bias generator output node coupled to the input bias node to provide the first bias voltage or the second bias voltage based on whether the bias generator circuit is supplied by the first or the second supply voltage.

Example 20 includes the subject matter of any of examples 13-19, and wherein the bias generator circuit has a first divider circuit with a first divider node to be coupled to the bias generator output node to provide the first bias voltage when the bias generator circuit is supplied by the first supply voltage, the bias generator circuit including a second divider circuit having a second divider node to be coupled to the bias generator output node to provide the second bias voltage when the bias generator circuit is supplied by the second supply voltage, the second bias voltage being larger than the first bias voltage.

Example 21 is a circuit that includes a supply node, a driver transistor, an EOS protection transistor, and an off-state protection transistor. The supply node is to receive a supply voltage. The driver transistor is coupled between the supply node and a regulator output node to provide a regulated voltage at the regulator output node. The EOS protection transistor is coupled at a junction node between the driver transistor and the regulated output node. The EOS protection transistor has a gate coupled to a bias node. The off-state protection transistor is coupled between the bias node and the junction node to provide the junction node with the bias voltage when the driver transistor is in an inactive state.

Example 22 includes the subject matter of example 21, and further comprises a full swing level shift circuit to control the off-state protection transistor.

Example 23 includes the subject matter of any of examples 21-22, and wherein the full swing level shift circuit comprises first and second transistor stacks coupled together through a current mirror configuration.

Example 24 includes the subject matter of any of examples 2-23, and wherein the full swing level shift circuit comprises first and second transistor stacks coupled together through a cross-coupled configuration.

Example 25 is a system that includes a processor IC and a power supply. The processor IC includes: (i) a functional circuit having a control input node, (ii) a level shift circuit having an output node coupled to the control input node to provide a level-shifted control voltage signal, the level shift circuit having an electrical overstress (EOS) protection transistor with a protection bias gate input node, and (iii) a bias generation circuit including: (a) a voltage divider circuit formed from a first plurality of transistors to establish a divider voltage, and (bi) an output section including a second plurality of transistors with a bias output node coupled to the protection bias gate input node to provide a bias output voltage corresponding to the divider voltage, the output section coupled to the voltage divider circuit to facilitate negative feedback control of the voltage divider circuit based on the bias output voltage. The power supply is coupled to the processor to provide it with power.

Example 26 includes the subject matter of example 25, and wherein the functional circuit is a low drop-out (LDO) circuit.

Example 27 includes the subject matter of any of examples 25-26, and wherein the control node is coupled to gates of one or more supply transistors to enable or disable the LDO.

Example 28 includes the subject matter of any of examples 25-27, and wherein the LDO includes a supply node to receive a supply voltage that is one of at least first and second supply voltage levels, the second level being larger than the first level, wherein the LDO includes a driver transistor coupled to an LDO output node to provide a regulated LDO output voltage, and a second driver transistor controllably coupled to the LDO output node to supplement power to the LDO output node when the supply is at the first supply voltage level.

Example 29 includes the subject matter of any of examples 25-28, and wherein the LDO comprises an EOS protection transistor coupled between the first driver transistor and the LDO output node.

Example 30 includes the subject matter of any of examples 25-29, and wherein the EOS protection transistor has a gate coupled to an LDO bias voltage that is one-half the LDO supply level voltage.

Example 31 includes the subject matter of any of examples 25-30, and wherein the functional circuit, level shift circuit, first plurality of transistors, and second plurality of transistors are thin-gate transistors.

Example 32 includes the subject matter of any of examples 25-31, and wherein the voltage divider circuit is coupled between a supply node with a supply voltage that is higher than an EOS level for the first and second plurality of transistors and a ground reference node, the divider voltage to be one-half the supply voltage level.

Example 33 includes the subject matter of any of examples 25-32, and wherein the output section is coupled to the voltage divider circuit at a gate of a control transistor from the first plurality of transistors to facilitate a first negative feedback lop.

Example 34 includes the subject matter of any of examples 25-33, and wherein at least one of the output section second plurality transistors is coupled to at least one of the first plurality of transistors in a current mirror configuration to provide a second negative feedback loop.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FcFET) transistors, or other transistor device types such as carbon nanotubes or spintronic devices.

In addition, well-known power/ground connections to integrated circuit (IC) chips and other components may or may not be shown within the presented figures, for simplicity of illustration and discussion, and so as not to obscure the disclosure. Moreover, a ground reference may be connected to a grounded node of a package or die, or it may correspond to a low supply reference level that is lower than an associated high supply reference but it does not necessarily have to be a 0 V ground in the literal sense. Further, arrangements may be shown in block diagram form in order to avoid obscuring the disclosure, and also in view of the fact that specifics with respect to implementation of such block diagram arrangements are dependent upon the platform within which the present disclosure is to be implemented.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, a system on a chip (SoC), an application processor, an integrated circuit or multi-chip package incorporating a combination of one or more of the aforesaid items.

While the invention has been described in terms of several embodiments, those skilled in the art will recognize that the invention is not limited to the embodiments described, and can be practiced with modification and alteration within the spirit and scope of the appended claims. The description is thus to be regarded as illustrative instead of limiting.

What is claimed is:

1. An apparatus, comprising:
a first circuit having a first input node;
a level shift circuit having an output node coupled to the first input node, the level shift circuit having an electrical overstress (EOS) protection transistor with a second input node; and
a bias generation circuit including: (i) a voltage divider circuit formed from a first plurality of transistors, and (ii) an output section including a second plurality of transistors with a second output node coupled to the second input node to provide a bias output voltage corresponding to a divider voltage, the output section coupled to the voltage divider circuit to facilitate negative feedback control of the voltage divider circuit based on the bias output voltage.

2. The apparatus of claim 1, wherein the first circuit is a low drop-out (LDO) circuit.

3. The apparatus of claim 2, wherein the first input node is coupled to gates of one or more supply transistors to enable or disable the LDO.

4. The apparatus of claim 3, wherein the LDO includes a supply node to receive a supply voltage that is one of at least first and second supply voltage levels, the second level being larger than the first level, wherein the LDO includes a first driver transistor coupled to an LDO output node to provide a regulated LDO output voltage, and a second driver transistor controllably coupled to the LDO output node to supplement power to the LDO output node when the supply is at the first supply voltage level.

5. The apparatus of claim 4, wherein the LDO comprises an EOS protection transistor coupled between the first driver transistor and the LDO output node.

6. The apparatus of claim 5, wherein the EOS protection transistor has a gate coupled to an LDO bias voltage that is one-half the LDO supply level voltage.

7. The apparatus of claim 1, wherein the first circuit, level shift circuit, first plurality of transistors, and second plurality of transistors are thin-gate transistors.

8. The apparatus of claim 1, wherein the voltage divider circuit is coupled between a supply node with a supply voltage that is higher than an EOS level for the first and second plurality of transistors and a ground reference node, the divider voltage to be one-half the supply voltage level.

9. The apparatus of claim 8, wherein the output section is coupled to the voltage divider circuit at a gate of a control transistor from the first plurality of transistors to facilitate a first negative feedback loop.

10. The apparatus of claim 9, wherein at least one of the output section second plurality of transistors is coupled to at least one of the first plurality of transistors in a current mirror configuration to provide a second negative feedback loop.

11. An integrated circuit having one or more first circuits, level shift circuits, and bias generation circuits as defined in claim 1.

12. A multi-chip package comprising at least one of the integrated circuits of claim 11.

13. A regulator circuit, comprising:
a supply node to receive a supply voltage that is one of at least first and second supply voltages, the second supply voltage being larger than the first supply voltage,
a first driver transistor coupled between the supply node and a regulator output node to provide a regulated voltage at the regulator output node; and
a second driver transistor controllably coupled between the supply node and the regulator output node to be active and supplement power to the regulator output node when the supply is at the first supply voltage and to be inactive when the supply node is at the second supply voltage.

14. The regulator circuit of claim 13, comprising one or more EOS protection transistors coupled between the supply node and the regulator output node, the one or more EOS protection transistors each having a gate coupled to an input bias node to receive a first bias voltage if the supply node is at the first supply voltage and to receive a second bias voltage if the supply node is at the second supply voltage.

15. The regulator circuit of claim 14, wherein a first of the one or more EOS protection transistors is coupled between the first driver transistor and the regulator output node.

16. The regulator circuit of claim 14, comprising a bias generator circuit having a bias generator output node coupled to the input bias node to provide the first bias voltage or the second bias voltage based on whether the bias generator circuit is supplied by the first or the second supply voltage.

17. The regulator circuit of claim 16, wherein the bias generator circuit has a first divider circuit with a first divider node to be coupled to the bias generator output node to provide the first bias voltage when the bias generator circuit is supplied by the first supply voltage, the bias generator circuit including a second divider circuit having a second divider node to be coupled to the bias generator output node to provide the second bias voltage when the bias generator circuit is supplied by the second supply voltage, the second bias voltage being larger than the first bias voltage.

18. An integrated circuit having one or more regulator circuits as recited in claim 13.

19. A multi-chip package comprising at least one of the integrated circuits of claim 18.

20. A circuit, comprising:
a supply node to receive a supply voltage;
a driver transistor coupled between the supply node and a regulator output node to provide a regulated voltage at the regulator output node;
an EOS protection transistor coupled at a junction node between the driver transistor and the regulated output node, the EOS protection transistor having a gate coupled to a bias node; and
an off-state protection transistor coupled between the bias node and the junction node to provide the junction node with the bias voltage when the driver transistor is in an inactive state.
